(19) United States
(12) Patent Application Publication
(10) Pub. No.: US 2012/0273041 A1
(43) Pub. Date: Nov. 1, 2012

(54) LIGHT CONCENTRATOR WITH TAPERED DICHROIC MATERIALS

(76) Inventor: Angus Wu, Corvallis, OR (US)

(21) Appl. No.: 13/096,045

(22) Filed: Apr. 28, 2011

(51) Int. Cl. H01L 31/0232; G02B 1/10; B05D 5/06

(52) U.S. Cl. 136/259; 427/162; 359/580

(57) ABSTRACT

Apparatus and methods are provided for use with solar energy. A substrate is defined by a parabolic cross-sectional shape or portion there of. A surface treatment having plural layers of dichroic materials is formed on the substrate. The layers are tapered in thickness, increasing from about a lower edge to about an upper edge. A spectral band of incident photonic energy is concentrated on a target by way of the surface treatment. The spectral band is consistent for a range of angles of incidence to the surface treatment.

### STATEMENT OF GOVERNMENT INTEREST

The invention that is the subject of this patent application was made with Government support under Subcontract No. CW135971, under Prime Contract No. HR0011-07-9-0005, through the Defense Advanced Research Projects Agency (DARPA). The Government has certain rights in this invention.

### BACKGROUND

Solar energy devices and apparatus make use of incident sunlight to heat water or other fluids, for direct conversion to electrical energy, and so on. Improvements in solar energy capture, energy transfer or conversion efficiency within such devices and systems is constantly sought after. The present teachings address the foregoing and other concerns.

### BRIEF DESCRIPTION OF THE DRAWINGS

The present embodiments will now be described, by way of example, with reference to the accompanying drawings, in which:

FIG. 1 is an end elevation view of a light concentrating apparatus according to one example of the present teachings;

FIG. 2 is an end elevation view of a system according to another example of the present teachings;

FIG. 3 is an end elevation view of a system according to another example of the present teachings;

FIG. 4 is a flow diagram depicting a method according to an example of the present teachings;

FIG. 5 is a schedule of a surface treatment according to one example of the present teachings;

FIG. 6 is a block diagram of a layering scheme according to another example of the present teachings;

FIG. 7 is a reflectance diagram according to an example;

FIG. 8 is a reflectance diagram according to an example of the present teachings;

FIG. 9 is an isometric view of a light concentrating apparatus according to an example of the present teachings.

### DETAILED DESCRIPTION

### Introduction

Apparatus and methods are provided for use with solar energy. A substrate is defined by a parabolic cross-sectional shape or portion there of. A surface treatment having plural layers of dichroic materials is formed on the substrate. The layers are tapered in thickness, increasing from a lower edge to an upper edge. A spectral band of incident photonic energy is concentrated on a target by way of the surface treatment. The spectral band is consistent for a range of angles of incidence to the surface treatment.

In one example, an apparatus includes a material having a cross-sectional shape defined by at least a segment of a parabola. The apparatus also includes a plurality of layers of respective dichroic materials formed on the material, such that a coated surface is defined. Each of the layers tapers in thickness from adjacent to a lower edge to adjacent to an upper edge of the coated surface. The coated surface is configured to concentrate photonic energies within a spectral band onto a target.

In another example, a solar energy device includes a photovoltaic cell configured to convert incident photonic energy into electrical energy. The solar energy device also includes a surface defined by a parabolic curvature. The solar energy device additionally includes at least two different dichroic materials disposed as layers on the surface so as to define a treated surface. Each of the layers increases in thickness from a first edge of the treated surface to a second edge of the treated surface that is opposite to the first edge. The treated surface is configured to concentrate a spectral band of photonic energies onto the photovoltaic cell

In yet another example, a method includes forming a material to define a surface having a cross-sectional shape that is at least a segment of a parabola. The method also includes forming alternating layers of at least two different dichroic materials on the surface. Each of layers increases in thickness from a first edge of the surface to a second edge of the surface opposite to the first edge so as to define a coated surface. The method further includes disposing the coated surface so as to concentrate incident light energy within a spectral band onto a target.

### Illustrative Coated Surface

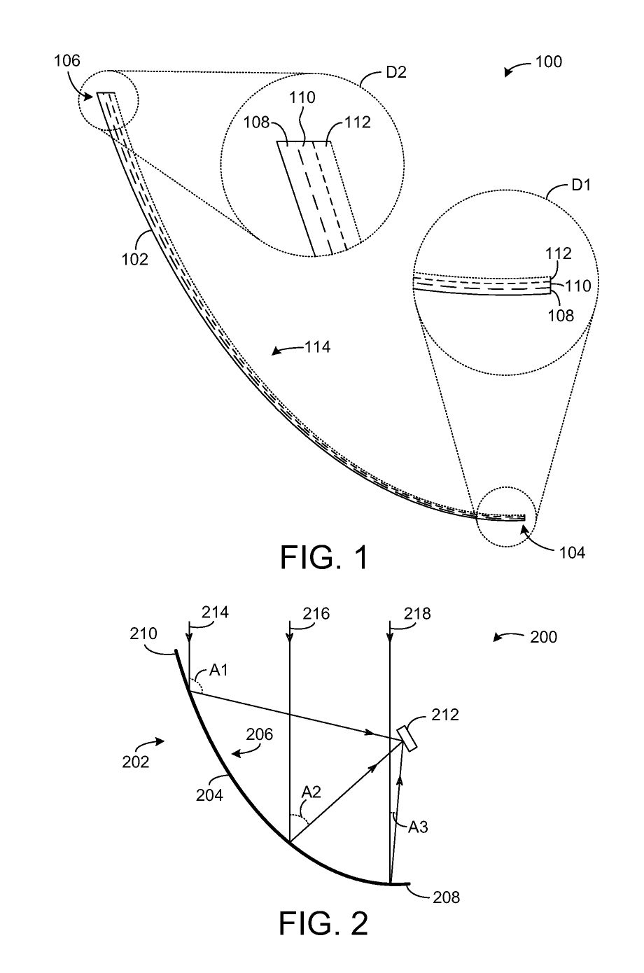

Reference is now directed to FIG. 1 which depicts an end elevation view of a light concentrating apparatus 100. The apparatus 100 is illustrative and non-limiting with respect to the present teachings. Thus, other apparatus, devices or systems can be configured and/or operated in accordance with the present teachings.

The apparatus 100 includes a substrate 102. The substrate 102 can be formed from any suitable rigid material that will retain a curved cross-sectional shape. Non-limiting examples of the substrate 102 include aluminum, brass, copper, transparent plastic, glass, thermoplastic, polyethylene naphthalate (PEN), and so on. Other suitable materials can also be used. The substrate 102 is formed so as to retain a cross-sectional shape of a segment of a parabola. The substrate 102 is also referred to as a parabolic surface 102. The coated surface 100 is defined by a lower edge 104 and an opposite, upper edge 106. The lower edge 104 is depicted in detail inset view “D1”, while the upper edge 106 is depicted in detail inset view “D2”.

The apparatus 100 also includes a plurality of dichroic materials 108, 110 and 112, respectively. The dichroic materials 108-112, inclusive, are disposed or formed on the substrate 102 as respective layers collectively defining a surface treatment 114. The surface treatment 114 includes only three dichroic material layers (108-112) in the interest of clarity. However, other surface treatments having any suitable number of dichroic materials layers (e.g., fifty, sixty, seventy, and so on) are contemplated by the present teachings.

In one example, the dichroic material 108, which is in direct contact with the substrate 102, is defined by or includes silicon dioxide (SiO₂). Also in the present example, the dichroic material 110 is defined by or includes niobium pentoxide (Nb₂O₅). Further in the present example, the dichroic material 112, which is the outermost layer away from the substrate 102, is defined by or includes silicon dioxide (SiO₂). In this way, the surface treatment 114 includes two respectively different dichroic materials arranged as three alternating layers. The present teachings contemplate the use of other types or numbers of dichroic materials, arranged as alternating or other orders of layers, as well.

Each dichroic material (or layer) 108-112 is tapered in thickness, having a lesser thickness at (or about) the lower edge 104 and increasing to a greater thickness at (or about) the upper edge 106. In another example, a non-linear thickness gradient is used. In yet another example, the dichroic materials 108-112 extend from near or adjacent to the lower edge 104 to near or adjacent to the upper edge 106.

The tapered thickness characteristic of the dichroic materials 108-112 is detailed in the inset views D1 and D2, respectively. In one example, each of the layers 108-112 increases linearly by thirteen percent in thickness from the lower edge 104 to the upper edge 106. Other percent increases or “slopes” can also be used depending on the range of incident angles from the lower edge 104 to the upper edge 106. Each of the layers 108-112 thus has a curved wedge-like cross-sectional shape or profile.

The thickening of the respective dichroic material layers 108, 110 and 112 corrects the angle of reflection for light rays of varying angles of incidence to the treated surface 114. In particular, various photonic energies within a spectral band are uniformly concentrated on a target region despite respectively different angles of incidence with respect to the light concentrating apparatus 100. Further discussion on spectral band light concentration is provided below.

### Illustrative Light Concentrator

Attention is now turned to FIG. 2, which depicts an end elevation view of a system 200 in accordance with another example of the present teachings. The system 200 is illustrative and non-limiting with respect to the present teachings. Other devices, apparatus and systems can also be used.

The system 200 includes a light concentrating apparatus (apparatus) 202. The apparatus 202 includes a substrate 204 defined by a parabolic or parabolic segment cross-sectional shape. Thus, the substrate 204 is also referred to as a parabolic surface 204 for purposes herein. The substrate 204 can be formed from any suitable material that will retain the segmented parabolic shape such as metal, glass, plastic, and so on. For purposes of example, it is assumed that the substrate 204 is formed from aluminum sheet metal. As such, the substrate 204 is opaque to light (photonic) energy. Other materials can also be used.

The apparatus 202 also includes a surface treatment 206 borne by an inner surface of the substrate 204. The surface treatment 206 is defined by plural layers of respective dichroic materials, which taper linearly from a lesser thickness at a lower edge 208 to a greater thickness at an upper edge 210 of the light concentrating apparatus 202. The surface treatment 206 therefore increases in thickness from the lower edge 208 to the upper edge 210 by virtue of the cross-sectional profile of the respective dichroic layers (e.g., 108-112). In one example, the surface treatment 206 includes sixty-two alternating layers of two different dichroic materials—namely, silicon dioxide (SiO₂) and niobium pentoxide (Nb₂O₅). Other numbers of layers, numbers of dichroic materials, or types of dichroic materials can also be used.

The system 200 further includes a target 212. The target 212 is disposed at a focal line or region defined by the apparatus 202. That is, the target 212 is located to receive concentrated photonic energy from the apparatus 202. In turn, the apparatus 202 is configured to concentrate photonic energy onto the target 212 by virtue of its segmented parabolic shape and the surface treatment 206. In one example, the target 212 is a photovoltaic cell (PV cell) 212 configured to convert incident light energy into electrical energy. Other targets can also be used.

Three illustrative light rays 214, 216 and 218, respectively, are incident to the apparatus 202. These light rays 214-218 are within a spectral band of photonic energies consistent with the reflective and refractive properties of the surface treatment 206. Specifically, the light rays 214, 216 and 218 are directed away from the apparatus 202, defined by interior angles “A1”, “A2” and “A3”, respectively. Each of the angles A1-A3 is the sum of the angle of incidence plus the angle of reflection for a given light ray 214-218, respectively. The result is that all three light rays 214-218 are concentrated on a common region or line where the target 212 is located.

The immediate foregoing applies to photonic energies within a predetermined spectral band, despite significantly different angles of incidence to the apparatus 202. In one example, the substrate 204 and the surface treatment 206 are such that photonic energies from about four-hundred nanometers to about seven-hundred-fifty nanometers in wavelength, having angles of incidence in the range of about twenty degrees to about fifty degrees of arc, are concentrated on the target 212. Other spectral bands or angles of incidence can be accommodated in accordance with other apparatus of the present teachings.

The apparatus 202 therefore exhibits characteristics analogous to those of a bandpass filter with respect to the light energy concentrated on the target 212. It is noted that photonic energies outside of spectral band (or pass-band) are absorbed by the apparatus 202 or are directed away so as to not strike the target 212.

### Another Illustrative Light Concentrator

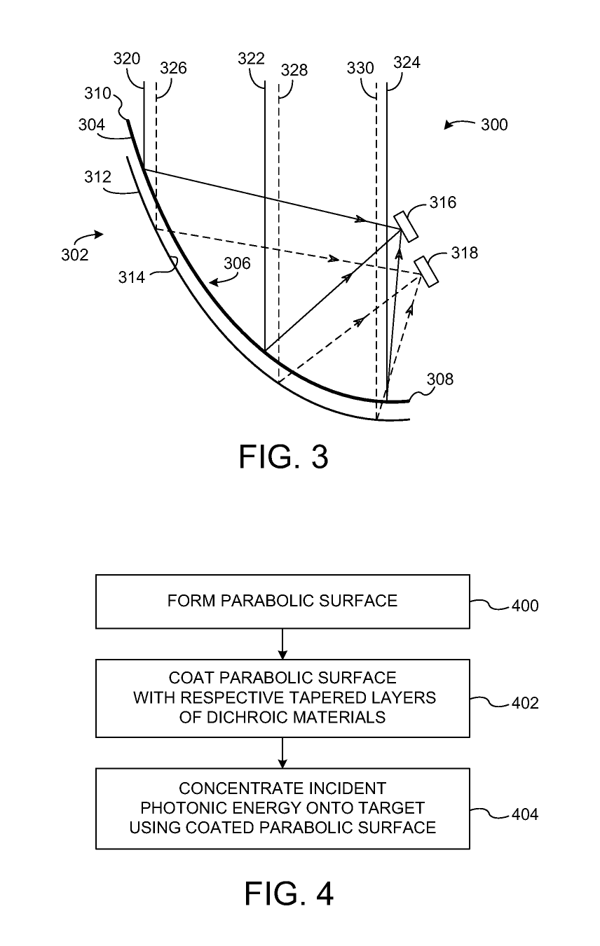

Reference is directed to FIG. 3, which depicts an end elevation view of a system 300 in accordance with another example of the present teachings. The system 300 is illustrative and non-limiting with respect to the present teachings. Other devices, apparatus and systems can also be used.

The system 300 includes a light concentrating apparatus (apparatus) 302. The apparatus 302 includes a substrate 304 defined by a parabolic or parabolic-segment cross-sectional shape, and having a surface treatment 306 thereon. The substrate 304 can be formed from any suitable transparent material that will retain the segmented parabolic shape such as glass, plastic, thermoplastic, and so on. For purposes of example, it is assumed that the substrate 304 is formed from thermoplastic. As such, the substrate 304 is transparent to light (photonic) energy. Other materials can also be used.

The surface treatment 306 is defined by plural layers of respective dichroic materials, which taper from a lesser thickness at a lower edge 308 to a greater thickness at an upper edge 310 of the light concentrating apparatus 302. The surface treatment 306 therefore increases in thickness from the lower edge 308 to the upper edge 310. In one example, the surface treatment 306 includes sixty-two alternating layers of two different dichroic materials—namely, silicon dioxide (SiO₂) and niobium pentoxide (Nb₂O₅). Other numbers of layers, numbers of dichroic materials, or types of dichroic materials can also be used.

The light concentrating apparatus 302 also includes a reflector 312. The reflector 312 is defined by a parabolic or parabolic-segment cross-sectional shape and is configured to reflect photonic energies incident thereto within one or more spectral bands. Thus, the reflector 312 is also referred to as a broad-band light reflector for purposes herein. The reflector 312 can be formed from any suitable material that will retain the segmented parabolic shape such as metal, glass, plastic, thermoplastic, and so on.

The reflector 312 is further defined by a reflected surface or coating 314. For purposes of example, it is assumed that the reflector 312 is formed from thermoplastic having an aluminum reflective coating 314 formed thereon by sputtering or another suitable technique. As such, the reflector 312 is opaque to and reflective of light (photonic) energy. The reflector 312 is disposed to receive and reflect light energy passing through the substrate 304 and the surface treatment 306.

The system 300 includes a target 316. The target 316 is disposed at a focal line or region defined by the surface treatment 306 and supporting substrate 304. In one example, the target 316 is a photovoltaic cell (PV cell) 316 configured to convert incident light energy into electrical energy. Other targets can also be used. The system further includes a target 318. The target 318 is disposed at a focal line or region defined by the reflector 312. In one example, the target 318 is a fluid-filled conduit 318 configured to heat a liquid or other medium by way of the incident photonic (infrared) energy. Other targets can also be used.

Three illustrative light rays 320, 322 and 324, respectively, are incident to the apparatus 302. These light rays 320-324 are within a spectral band of photonic energies consistent with the reflective and refractive properties of the surface treatment 306. The light rays 320, 322 and 324 are directed away from the apparatus 302 and concentrated onto a common region or line where the target 316 is located. In one example, the spectral band (or pass-band) defined by the surface treatment 306 is about four-hundred to about seven-hundred-fifty nanometers in wavelength. In another example, the spectral band is about four-hundred to about eight-hundred-ninety nanometers. Other spectral bands can also be defined for other surface treatments according to the present teachings.

Three other illustrative light rays 326, 328 and 330, respectively, are incident to the apparatus 302. These light rays 326-330 are outside of the spectral band of the surface treatment 306. The light rays 326-330 therefore pass through the surface treatment 306 and the substrate 304, and are concentrated onto the target 318 by way of the reflector 312. Thus, at least some light energy outside of the spectral band of the surface treatment 306 is “captured” and used, rather than being absorbed, scattered, transmitted or otherwise unutilized.

The respective targets 316 and 318 can be selected or “optimized” in accordance with the spectral energies that each is subjected to. For example, the surface treatment 306 can be defined and formed in accordance with the spectral characteristics of the PV cell 316 (e.g., high-energy and mid-energy photons). In turn, the target 318 can be blackened, fluid-filled conduit for heating a fluid medium by way of absorption of infrared energy that are outside of the pass-band of the surface treatment 306 (e.g., low-energy photons). Other optimization strategies can also be used.

### Illustrative Method

Reference is now made to FIG. 4, which depicts a flow diagram of a method according to the present teachings. The method of FIG. 4 includes particular operations and order of execution. However, other methods including other operations, omitting one or more of the depicted operations, and/or proceeding in other orders of execution can also be used according to the present teachings. Thus, the method of FIG. 4 is illustrative and non-limiting in nature. Reference is made to FIGS. 1 and 2 in the interest of understanding FIG. 4.

At 400, a parabolic surface is formed. For purposes of a present example, it is assumed that a substrate 102 is formed from thermoplastic such that a cross-sectional shape of a segment of a parabola is defined and maintained. This substrate 102 is also referred to as a parabolic surface 102 for purposes of the present example.

At 402, the parabolic surface is coated with respective tapered layers of dichroic materials. For purposes of the present example, the substrate 102, formed at step 400 above, is now coated with alternating layers (e.g., 108-112) of silicon dioxide and niobium pentoxide, respectively, so that a surface treatment 114 is defined. These respective layers are tapered so as to increase in thickness from a lower edge 104 to an upper edge 106 of the substrate 102. Thus, a plurality of curved wedge-like layers or “slabs” of dichroic material are formed or laid down. In another example, other materials or layering schemes can be used. A coated parabolic surface is thus defined.

At 404, incident photonic energy is concentrated onto a target using the coated parabolic surface. Within the present example, it is assumed that a light concentrating apparatus 202 is defined by the coated parabolic surface defined at step 402 above. Incident light energy—including respective rays 214-218—is concentrated onto a target 212. The target 212 is defined by a photovoltaic cell generally optimized for electrical generation in accordance with the spectral band of the photonic energy concentrated thereon.

It is to be understood that the method described above can be suitably varied in accordance with the present teachings. In one example, a sheet of thermoplastic is first coated with respective layers of dichroic material (i.e., step 402), and thereafter thermoformed to define the desired reflector (parabolic) cross-sectional shape (i.e., step 400). Other variations can also be used or performed.

### Illustrative Surface Treatment

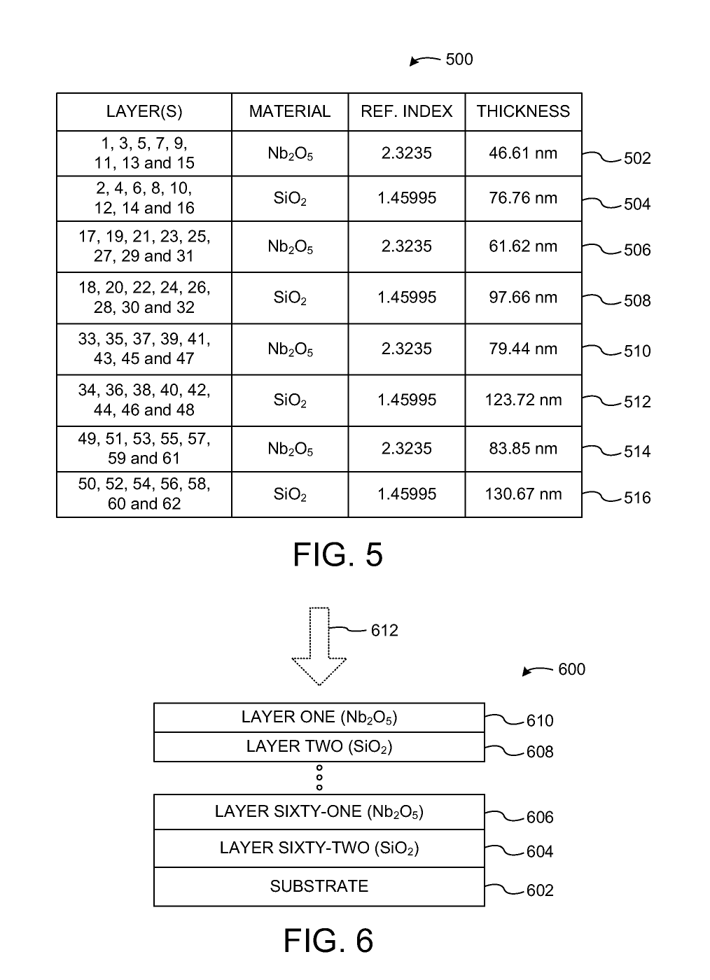

Attention is now directed to FIG. 5, which depicts a schedule or table of a surface treatment 500 according to the present teachings. The surface treatment 500 is illustrative and non-limiting with respect to the present teachings. Thus, other surface treatments, layering schemes, dichroic materials, and so on, can be configured or used in accordance with the present teachings.

The surface treatment 500 includes dichroic materials, their respective refractive indices and their respective average thicknesses for a total of sixty-two layers. For example, line 502 describes niobium pentoxide (Nb₂O₅) having an average thickness of forty-six-point-six-one nanometers (46.61 nm) for each of the odd-numbered layers one through fifteen, inclusive. In turn, line 504 includes silicon dioxide (SiO₂) having an average thickness of seventy-six-point-seven-six nanometers (76.76 nm) for each of the even-numbered layers two through sixteen, inclusive. Similar information is included in the other lines 506 through 516, inclusive.

It is noted that the respective layers one through sixty-two increase in average thickness in groupings of layers, the relatively thicker layers being adjacent to a supporting substrate (see FIG. 6). It is also noted that respective dichroic materials of the surface treatment 500 alternate in the layering scheme. The surface treatment 500 is illustrative of any number of surface treatments contemplated by the present teachings.

The present teachings contemplate any number of examples in which alternating layers of relatively high optical index material like Nb₂O₅ and low optical index material like SiO₂ are formed to achieve high reflective band pass filter. Non-limiting examples of high index materials include titanium dioxide (TiO₂), tantalum pentoxide (Ta₂O₅), zirconium pentoxide (Zr₂O₅), hafnium dioxide (HfO₂), and so on. Non-limiting examples of relatively low index materials include silicon dioxide (SiO₂), magnesium fluoride (MgF₂), aluminum oxide (Al₂O₃), and so on. The number of layers and their respective thicknesses can be varied to achieve different reflective spectral bandwidths and amplitudes.

### Illustrative Layering Scheme

Attention is now directed to FIG. 6, which depicts a block diagram of a layering scheme 600 according to the present teachings. The layer scheme 600 is illustrative and non-limiting with respect to the present teachings. Other layer schemes, materials, device and systems can also be used. The layering scheme 600 is depicted in a planar cross-sectional shape, having constant thickness, in the interest of clarity. However, it is to be understood that the layering scheme 600 can be applied to curved (i.e., parabolic) cross-sectional surface or by way of dichroic materials having tapered thicknesses.

The layer scheme 600 includes a substrate 602. The substrate 602 can be formed from any suitable material such as metal, plastic, thermoplastic, glass, and so on. The layering scheme 600 also includes a layer 604 that is formed or provided in contact with the substrate 602. The layer 604 is numbered sixty-two of a same number of dichroic material layers. The layer 604 is defined by silicon dioxide.

The layering scheme 600 also includes a layer 606 that is formed or provided in contact with the layer 604. The layer 606 is numbered sixty-one of sixty-two dichroic material layers. The layer 606 is defined by niobium pentoxide. The layering scheme 600 also depicts layers 608 and 610, being number two and one, respectively, of sixty-two dichroic material layers. Thus, the layer 610 is the furthest away from the substrate 602 and is the first layer subject to incident sunlight 612. In one example, the surface treatment 500 is formed in accordance with the layering scheme 600 and is supported on a substrate 602 having a parabolic cross-sectional shape (e.g., 102).

### Illustrative Reflectance Diagrams

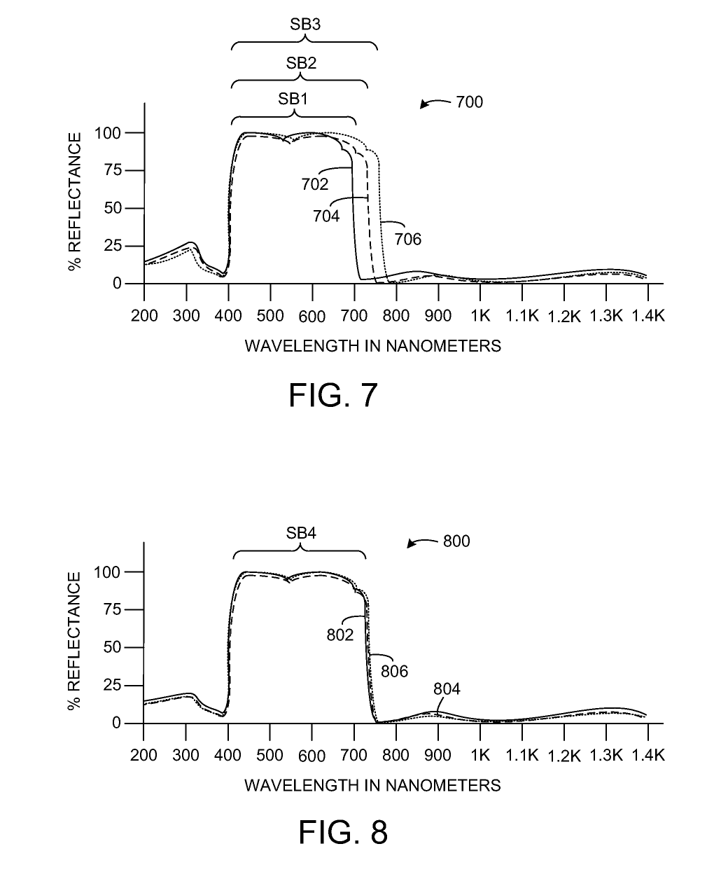

Reference is made now to FIG. 7, which depicts a reflectance diagram 700. The diagram 700 includes a range of wavelengths of photonic energies versus reflectance of those respective energies by way of a parabolic surface (e.g., 102) having a surface treatment. The diagram 700 is illustrative and intended to convey operational concepts. The diagram 700 corresponds to a surface treatment having a plurality of dichroic material layers, each layer being of constant and uniform thickness overall of the supporting parabolic surface. Thus, the diagram 700 is consistent with dichroic material layers that are not tapered in thickness.

The diagram 700 includes a locus 702 corresponding to photonic energy striking the surface treatment at about fifty degrees angle of incidence. The locus 702 includes photonic energies ranging in wavelength from about two-hundred to about fourteen-hundred nanometers. The locus 702 includes a spectral band “SB1” ranging from about four-hundred to about seven-hundred nanometers in wavelength, corresponding to about ninety-percent or greater reflection. Thus, photonic energies within the spectral band SB1 are almost entirely reflected away from the surface treatment, rather than being absorbed or passing there through.

The diagram 700 includes a locus 704 corresponding to photonic energy striking the surface treatment at about thirty-eight degrees angle of incidence. The locus 704 includes a spectral band “SB2” ranging from about four-hundred to about seven-hundred-fifty nanometers in wavelength, corresponding to about ninety-percent or greater reflection.

The diagram 700 includes a locus 706 corresponding to photonic energy striking the surface treatment at about twenty degrees angle of incidence. The locus 706 includes a spectral band “SB3” ranging from about four-hundred to about seven-hundred-seventy nanometers in wavelength, corresponding to about ninety-percent or greater reflection.

It is note that the respective spectral bands or “pass-bands” SB1, SB2 and SB3 are inconsistent with respect to their greater cutoff or roll-off wavelengths. In other words, the spectral bands SB1-SB3 end at about seven-hundred, seven-hundred-fifty and seven-hundred-eighty nanometers, respectively. This means that the surface treatment represented by the diagram 700 exhibits notably different light concentrating performance as a function of angle of incidence to the surface treatment. Such performance is not ideal and results in absorbed, passed or generally “lost” photonic energy that is not concentrated to a corresponding target (e.g., 212).

Attention is now directed to FIG. 8, which depicts a reflectance diagram 800. The diagram 800 includes a range of wavelengths of photonic energies versus reflectance of those respective energies by way of a parabolic surface having a surface treatment. The diagram 800 corresponds to a surface treatment (e.g., 500) having a plurality of dichroic material layers, each layer being of linearly or nonlinearly increasing thickness from a lower edge (e.g., 208) to an upper edge (e.g., 210) of the parabolic surface (e.g. 204). Thus, the diagram 800 is consistent with dichroic material layers defined and formed in accordance with the present teachings.

The diagram 800 includes a locus 802 corresponding to photonic energy striking the surface treatment at about fifty degrees angle of incidence. The locus 802 includes photonic energies ranging in wavelength from about two-hundred to about fourteen-hundred nanometers. The locus 802 includes a spectral band “SB4” of photonic energies ranging from about four-hundred to about seven-hundred-fifty nanometers in wavelength, corresponding to about ninety-percent or greater reflection. The photonic energies within the spectral band SB4 are almost entirely reflected away from the surface treatment, rather than being absorbed or passing there through.

The diagram 800 includes a locus 804 corresponding to photonic energy striking the surface treatment at about thirty-eight degrees angle of incidence. The locus 804 includes a range within the spectral band SB4 corresponding to about ninety-percent or greater reflection. The diagram 800 includes a locus 806 corresponding to photonic energy striking the surface treatment at about twenty degrees angle of incidence. The locus 806 includes a range within the spectral band SB4 corresponding to about ninety-percent or greater reflection.

It is noted that the respective loci 802-806 have respective pass-bands that are generally consistent within the range defined by SB4—namely, about four-hundred to about seven-hundred-fifty nanometers. This means that the surface treatment (e.g., 500) represented by the diagram 800 exhibits consistent light concentrating performance as a function of angle of incidence. Such performance is nearly ideal and results in essentially all of the photonic energy within a spectral band being concentrated on a corresponding target (e.g., 212).

### Illustrative Light Concentrating Apparatus

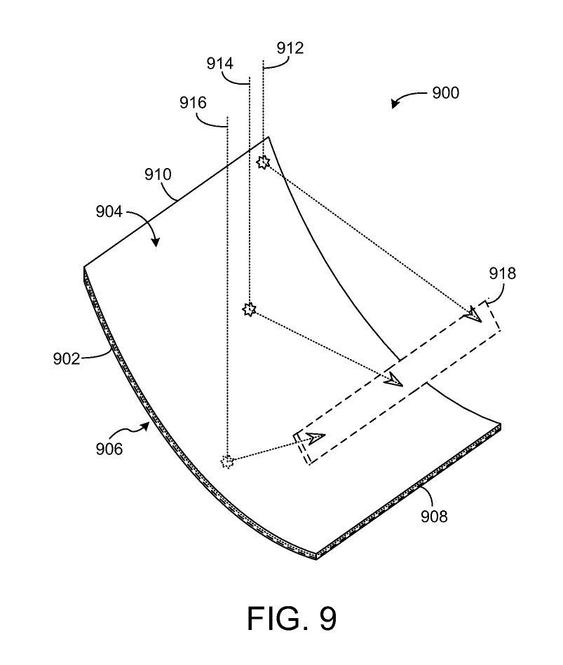

Attention is now directed to FIG. 9, which depicts an isometric view of a light concentrating apparatus (apparatus) 900. The apparatus 900 is illustrative and non-limiting with respect to the present teachings. Thus, other light concentrating apparatus, devices or systems can be configured and/or operated in accordance with the present teachings.

The apparatus 900 includes a substrate 902. The substrate 902 can be defined by any material that can be formed to and retain a parabolic or segmented parabolic cross-sectional shape. For purposes of example, the substrate 902 is understood to be formed form aluminum. Other materials can also be used.

The apparatus 900 includes a surface treatment 904 borne by or formed upon the substrate 902. The surface treatment 904 includes a plurality of layers of respective dichroic materials arranged as a collection 906 of respective layers. Each of the layers increases linearly or nonlinearly in thickness from a lower edge 908 to an upper edge 910 of the surface treatment 904. The apparatus 900 is also referred to as a coated surface 900 by virtue of the surface treatment 904.

In one example, the surface treatment 904 is equivalent to the surface treatment 500. In one example, the surface treatment 904 is defined by a spectral band consistent with the spectral band SB4 of the diagram 800. Other configurations, dichroic materials or layering schemes can also be used.

During normal operation, incident light (photonic energy) strikes the surface treatment 904 at a multitude of respective incident angles. Three illustrative rays of light 912, 914 and 916, respectively, are depicted. It is to be understood that the entire area of the surface treatment 904 is subject to incident solar radiation during typical normal use.

The surface treatment 904, by virtue of the parabolic cross-section of the substrate 902, concentrates such incident light rays 912-916 upon a target 918. Such a target 918 can be variously defined by, for example, a photovoltaic cell, a fluid-filled thermal conduit, a communications receiver, a sensor, and so on.

In general, and without limitation, the present teachings contemplate light concentrators for use with solar energy. A light concentrator has a substrate formed to retain a parabolic cross-sectional shape, or at least a segment of such a parabola. A surface treatment including a plurality of layers of dichroic materials is formed on or otherwise borne by the substrate. Each layer of dichroic material increases in thickness from a lower edge to an upper edge of the light concentrator.

The tapered dichroic materials concentrate light (photonic) energy within a spectral band onto a target region, such as a photovoltaic cell, thermal conduit, and so on. The spectral band is generally sharply defined and continuous between a lesser and a greater photonic wavelength. Typically, the photonic energies within the spectral band are concentrated on the target region at greater than ninety-percent reflectance.

In some examples, photonic energies passing through the surface treatment and supporting substrate are concentrated onto another target region by way of a parabolic reflective surface with a different reflective bandpass coating design. Thus, the present teachings contemplate compound designs having plural light concentrating elements directed to distinct and respective targets. Targets can thus be selected or optimized for operation in accordance with the spectral band concentrated thereon.

In general, the foregoing description is intended to be illustrative and not restrictive. Many embodiments and applications other than the examples provided would be apparent to those of ordinary skill in the art upon reading the above description. The scope of the invention should be determined, not with reference to the above description, but should instead be determined with reference to the appended claims, along with the full scope of equivalents to which such claims are entitled. It is anticipated and intended that future developments will occur in the arts discussed herein, and that the disclosed systems and methods will be incorporated into such future embodiments. In sum, it should be understood that the invention is capable of modification and variation and is limited only by the following claims.

What is claimed is:

1. An apparatus, comprising:
a material having a cross-sectional shape defined by at least a segment of a parabola; and
a plurality of layers of respective dichroic materials formed on the material so as to define a coated surface, each of the layers tapering in thickness from about a lower edge to about an upper edge of the coated surface, the coated surface to concentrate photonic energies within a spectral band onto a target.

2. The apparatus of claim 1, the dichroic materials further defined by at least two distinct dichroic materials formed as respective layers on the coated surface.

3. The apparatus according to claim 1, the dichroic materials including two or more of niobium pentoxide (Nb₂O₅), silicon dioxide (SiO₂), titanium dioxide (TiO2), tantalum pentoxide (Ta2O5), zirconium pentoxide (Zr2O5), hafnium dioxide (HfO2), magnesium fluoride (MgF2) or aluminum oxide (Al2O3).

4. The apparatus according to claim 1, the material being transparent, the apparatus further including a reflective parabolic surface to concentrate photonic energies passing through the coated surface onto a different target.

5. The apparatus according to claim 1, each of the layers tapering from a lesser thickness at about the lower edge to a greater thickness at about the upper edge of the coated surface.

6. The apparatus according to claim 1, the target including a photovoltaic cell.

7. The apparatus according to claim 1, the spectral band defined by a range of photonic energies corresponding to characteristics of a photovoltaic cell.

8. The apparatus according to claim 1, the material being formed from at least a metal, or a polycarbonate, or a plastic, or a thermoplastic.

9. A solar energy device, comprising:
a photovoltaic cell to convert incident photonic energy into electrical energy;
a surface defined by a parabolic curvature; and
at least two different dichroic materials disposed as layers on the surface to define a treated surface, each of the layers increasing in thickness from about a first edge of the treated surface to about a second edge of the treated surface opposite the first edge, the treated surface to concentrate a spectral band of photonic energies onto the photovoltaic cell.

10. The solar energy device according to claim 9, the at least two different dichroic materials including niobium pentoxide (Nb₂O₅), silicon dioxide (SiO₂), titanium dioxide (TiO2), tantalum pentoxide (Ta2O5), zirconium pentoxide (Zr2O5), hafnium dioxide (HfO2), magnesium fluoride (MgF2) or aluminum oxide (Al2O3) disposed as alternating layers on the treated surface.

11. The solar energy device according to claim 9, the parabolic curvature to reflect photonic energies within the spectral band having angles of incidence from at least zero degrees to at least sixty degrees onto the photovoltaic cell.

12. The solar energy device according to claim 9, each of the layers increasing in thickness from about the first edge to about the second edge such that each layer is defined by a curved wedge-like cross-sectional shape.

13. A method, comprising:
forming a material to define a surface having a cross-sectional shape of at least a segment of a parabola;
forming alternating layers of two different dichroic materials on the surface, each of layers increasing in thickness from about a first edge of the surface to about a second edge of the surface opposite the first so as to define a coated surface; and
disposing the coated surface so as to concentrate incident light energy within a spectral band onto a target.

14. The method according to claim 13 further comprising:
forming a material to define a reflective surface having a parabolic cross-sectional shape; and
disposing the reflective surface so as to concentrate light energy passing through the coated surface onto another target.

15. The method according to claim 13, the layers of dichroic material formed adjacent to the surface having respective thicknesses that are greater than those of the layers formed away from the surface.
